(19) United States
(12) Patent Application Publication
(10) Pub. No.: US 2025/0380586 A1
(43) Pub. Date: Dec. 11, 2025

(54) DISPLAY DEVICE

(71) Applicant: Samsung Display Co., Ltd., Yongin-si (KR)

(72) Inventors: Kyung Bae KIM, Yongin-si (KR); Jin Seon KWAK, Yongin-si (KR); Keon Min OH, Yongin-si (KR); Yun Jang PYUN, Yongin-si (KR)

(21) Appl. No.: 19/205,805

(22) Filed: May 12, 2025

(30) Foreign Application Priority Data
Jun. 10, 2024 (KR) 10-2024-0074955

(51) Int. Cl. H10K 59/131; H10K 50/19; H10K 59/12; H10K 59/122; H10K 59/124; H10K 59/80; H10K 102/00

(52) U.S. Cl. CPC H10K 59/131; H10K 59/124; H10K 59/80515; H10K 59/80516; H10K 59/878; H10K 50/19; H10K 59/1201; H10K 59/122; H10K 2102/351

(57) ABSTRACT

A display device includes: a substrate; an insulating film on the substrate; a central metal portion in a central via hole of the insulating film and an outer metal portion in an outer via hole of the insulating film; a first electrode on the central metal portion and the outer metal portion; a pixel defining film on the first electrode; a light-emitting layer on the first electrode and the pixel defining film; and a second electrode on the light-emitting layer, wherein the central metal portion and the outer metal portion overlap an emission area defined by the pixel defining film.

### CROSS-REFERENCE TO RELATED APPLICATION

The present application claims priority to and the benefit of Korean Patent Application No. 10-2024-0074955, filed on Jun. 10, 2024, in the Korean Intellectual Property Office, the entire disclosure of which is incorporated herein by reference.

### BACKGROUND

### 1. Field

Aspects of some embodiments of the present disclosure relate to a display device and an electronic device.

### 2. Description of the Related Art

A head mounted display (HMD) is an image display device that may be worn on a user's head in the form of glasses or helmets to form a focus at a close distance in front of the user's eyes. The head mounted display may implement virtual reality (VR) or augmented reality (AR).

The head mounted display magnifies images displayed on a small display device by using a plurality of lenses, and displays the magnified images. Therefore, the display device applied to the head mounted display may desirably provide high-resolution images, for example, images with a resolution of 3000 PPI (Pixels Per Inch) or higher. To this end, an organic light-emitting diode on silicon (OLEDoS), which is a high-resolution small organic light-emitting display device, may be used as the display device applied to the head mounted display. The OLEDOS is an image display device in which an organic light-emitting diode (OLED) is located on a semiconductor wafer substrate on which a complementary metal oxide semiconductor (CMOS) is located.

The above information disclosed in this Background section is only for enhancement of understanding of the background and therefore the information discussed in this Background section does not necessarily constitute prior art.

### SUMMARY

Aspects of some embodiments of the present disclosure relate to a display device and an electronic device, and for example, to a display device and an electronic device capable of relatively improving image quality.

According to some embodiments of the present disclosure, a display device includes: a substrate; an insulating film on the substrate; a central metal portion in a central via hole of the insulating film and an outer metal portion in an outer via hole of the insulating film; a first electrode on the central metal portion and the outer metal portion; a pixel defining film on the first electrode; a light-emitting layer on the first electrode and the pixel defining film; and a second electrode on the light-emitting layer, wherein the central metal portion and the outer metal portion overlap an emission area defined by the pixel defining film.

According to some embodiments, in the emission area, a width of the outer metal portion is greater than a width of the central metal portion.

According to some embodiments, a thickness of the central metal portion is greater than a thickness of the outer metal portion.

According to some embodiments, a thickness of the insulating film is greater than a thickness of the central metal portion and a thickness of the outer metal portion.

According to some embodiments, the thickness of the central metal portion is greater than the thickness of the outer metal portion, and is less than the thickness of the insulating film.

According to some embodiments, the central metal portion overlaps a center of the emission area, and the outer metal portion overlaps an edge of the emission area.

According to some embodiments, the first electrode has a central groove in an area overlapping the central metal portion, and has an outer groove in an area overlapping the outer metal portion.

According to some embodiments, a width of the outer groove is greater than a width of the central groove.

According to some embodiments, a depth of the outer groove is greater than a depth of the central groove.

According to some embodiments, in a plan view, an area of the outer metal portion is larger than an area of the central metal portion.

According to some embodiments, the central metal portion comprises a plurality of central metal portions spaced apart from each other.

According to some embodiments, in a plan view, an area of the outer metal portion is larger than a total area of the plurality of central metal portions.

According to some embodiments, in a plan view, the outer metal portion surrounds the central metal portion.

According to some embodiments, in a plan view, the emission area surrounds the central metal portion and the outer metal portion.

According to some embodiments, the central via hole and the outer via hole overlap the emission area.

According to some embodiments, in a plan view, the emission area surrounds the central via hole and the outer via hole.

According to some embodiments, the display device further comprises a reflective electrode layer under the insulating film.

According to some embodiments, the reflective electrode layer is connected to at least one of the central metal portion or the outer metal portion.

According to some embodiments, the reflective electrode layer is connected to at least one of the central metal portion or the outer metal portion in the emission area.

According to some embodiments, the central metal portion and the outer metal portion do not overlap the pixel defining film.

According to some embodiments, the display device according to some embodiments may provide the following effects.

According to some embodiments, as the concentration of light at the center of an emission area is improved and the luminance of the light at the edge of the emission area is improved, the image quality of the display device may be relatively improved.

According to some embodiments of the present disclosure, an electronic device comprising: a display device including a screen, wherein the display device comprises: a substrate; an insulating film on the substrate; a central metal portion in a central via hole of the insulating film and an outer metal portion in an outer via hole of the insulating film; a first electrode on the central metal portion and the outer metal portion; a pixel defining film on the first electrode; a light-emitting layer on the first electrode and the pixel defining film; and a second electrode on the light-emitting layer, wherein the central metal portion and the outer metal portion overlap an emission area defined by the pixel defining film.

According to some embodiments, as the area of the emission area is increased, the opening ratio of pixels may be relatively improved.

The characteristics of embodiments according to the present disclosure are not limited to the above-described characteristics and other characteristics which are not described herein will become more apparent to those skilled in the art from the following description.

### BRIEF DESCRIPTION OF THE DRAWINGS

The above and other aspects and characteristics of embodiments according to the present disclosure will become more apparent by describing in more detail aspects of some embodiments thereof with reference to the attached drawings, in which:

FIG. 1 is an exploded perspective view showing a display device according to some embodiments;

FIG. 2 is a block diagram illustrating a display device according to some embodiments;

FIG. 3 is an equivalent circuit diagram of a first pixel according to some embodiments;

FIG. 4 is a layout diagram illustrating an example of a display panel according to some embodiments;

FIGS. 5 and 6 are layout diagrams illustrating embodiments of the display area of FIG. 4;

FIG. 7 is a cross-sectional view illustrating an example of a display panel taken along the line II-II′ of FIG. 5;

FIG. 8 is a plan view of the display device according to some embodiments;

FIG. 9 is a diagram illustrating a via and an emission area of FIG. 8;

FIG. 10 is a diagram illustrating a first electrode and the emission area of FIG. 8;

FIG. 11 is a cross-sectional view taken along the line II-II′ of FIG. 8;

FIG. 12 is a diagram for explaining the principle of the improvement of the correction of light at the center of the first electrode in the display device according to some embodiments;

FIG. 13 is a diagram for explaining the principle of improvement of the correction of light at the outer portion of the first electrode in the display device according to some embodiments;

FIG. 14 is a plan view of the display device 10 according to some embodiments;

FIG. 15 is a diagram illustrating the via and the emission area of FIG. 14;

FIG. 16 is a diagram illustrating the first electrode and the emission area of FIG. 14;

FIGS. 17 to 22 are process cross-sectional views illustrating a method of manufacturing the display device according to some embodiments;

FIG. 23 is a perspective view illustrating a head mounted display according to some embodiments;

FIG. 24 is an exploded perspective view illustrating an example of the head mounted display of FIG. 23; and

FIG. 25 is a perspective view illustrating a head mounted display according to some embodiments.

FIG. 26 is a block diagram of an electronic device according to one embodiment.

FIGS. 27, 28, and 29 are schematic diagrams of electronic devices according to various embodiments.

### DETAILED DESCRIPTION

Aspects of some embodiments of the present disclosure will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments will be described in more detail with reference to the accompanying drawings.

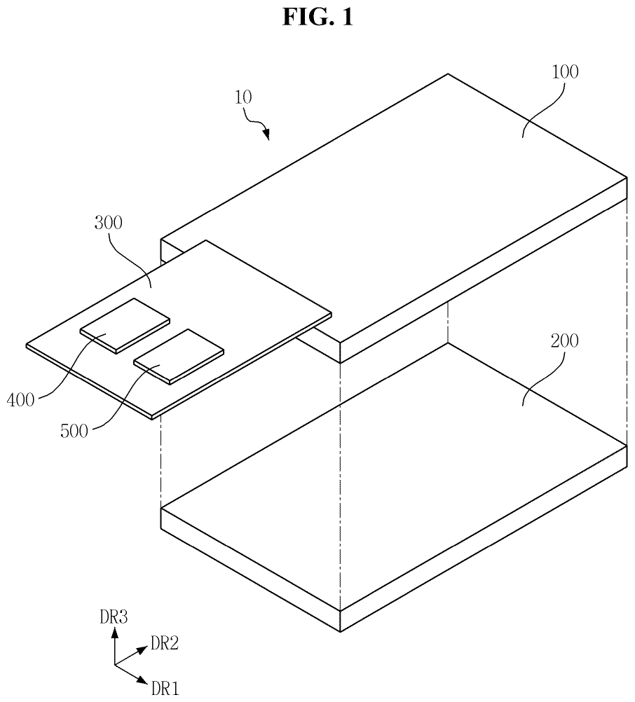

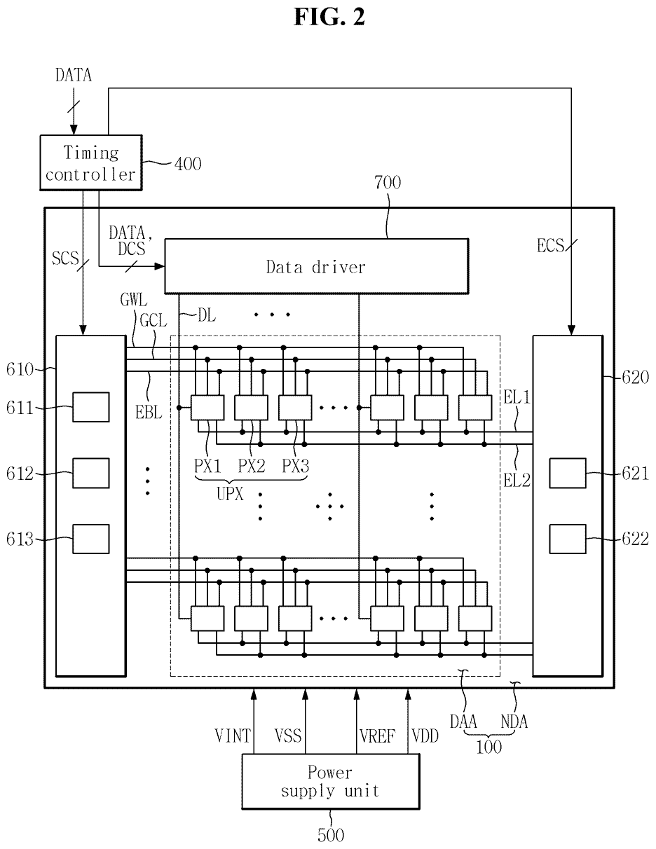

FIG. 1 is an exploded perspective view showing a display device 10 according to some embodiments. FIG. 2 is a block diagram illustrating a display 10 device according to some embodiments.

Referring to FIGS. 1 and 2, a display device 10 according to some embodiments is a device displaying moving images (e.g., video images) or still images (e.g., static images). The display device 10 according to some embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to some embodiments may be applied as a display unit of a television, a laptop, a monitor, a billboard, or an Internet-of-Things (IoT) terminal. Alternatively, the display device 10 according to some embodiments may be applied to a smart watch, a watch phone, a head mounted display (HMD) for implementing virtual reality and augmented reality, and the like.

The display device 10 according to some embodiments includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a curvature (e.g., a set or predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but embodiments according to the present disclosure are not limited thereto.

The display panel 100 includes a display area DAA displaying an image and a non-display area NDA not displaying an image as shown in FIG. 2.

The display area DAA includes a plurality of pixels PX, a plurality of scan lines SL, a plurality of emission control lines EL, and a plurality of data lines DL.

The plurality of pixels PX may be arranged in a matrix form or configuration in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

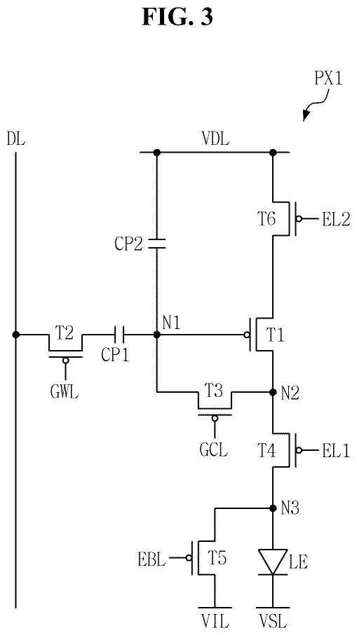

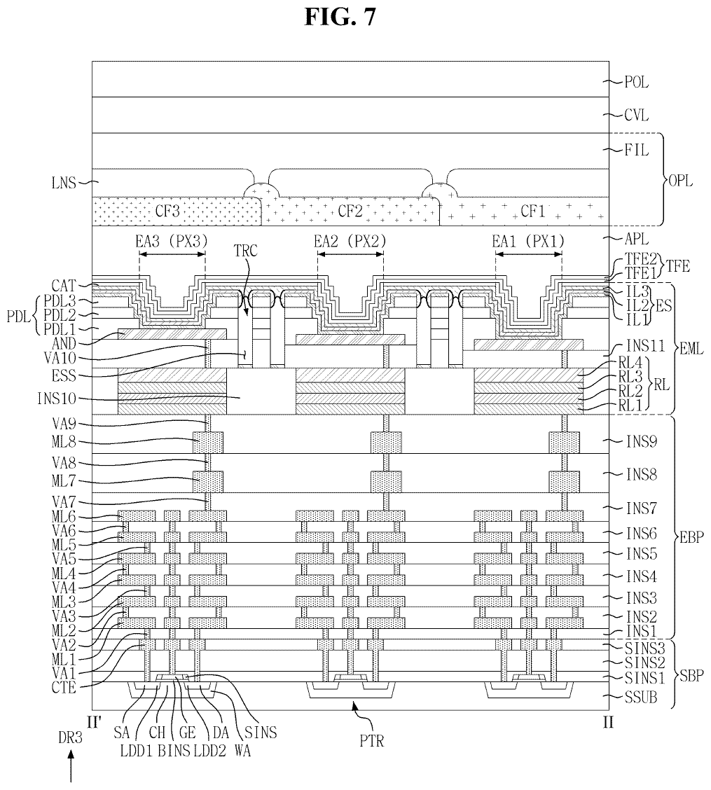

Each of a plurality of unit pixels UPX includes a plurality of pixels PX1, PX2, and PX3. The plurality of pixels PX1, PX2, and PX3 may include a plurality of pixel transistors as shown in FIG. 3, and the plurality of pixel transistors are formed through a semiconductor process and may be located on a semiconductor substrate SSUB (see FIG. 7). For example, the plurality of pixel transistors of a data driver 700 may be formed of complementary metal oxide semiconductor (CMOS).

Each of the plurality of pixels PX1, PX2, and PX3 may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the plurality of pixels PX1, PX2, and PX3 may receive a data voltage of the data line DL in response to a write scan signal of the write scan line GWL, and emit light from the light-emitting element according to the data voltage.

The non-display area NDA includes a scan driver 610, an emission driver 620, and a data driver 700.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed of CMOS. Although it is illustrated in FIG. 2 that the scan driver 610 is located on the left side of the display area DAA and the emission driver 620 is located on the right side of the display area DAA, embodiments according to the present disclosure are not limited thereto. For example, the scan driver 610 and the emission driver 620 may be located on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines EBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the pixels PX1, PX2, and PX3 are selected by the write scan signal of the scan driver 610, and data voltages may be supplied to the selected pixels PX1, PX2, and PX3.

The heat dissipation layer 200 may overlap the display panel 100 in a third direction DR3, which is the thickness direction of the display panel 100. The heat dissipation layer 200 may be located on one surface of the display panel 100, for example, on the rear surface thereof. The heat dissipation layer 200 serves to dissipate heat generated from the display panel 100. The heat dissipation layer 200 may include a metal layer such as graphite, silver (Ag), copper (Cu), or aluminum (AI) having high thermal conductivity.

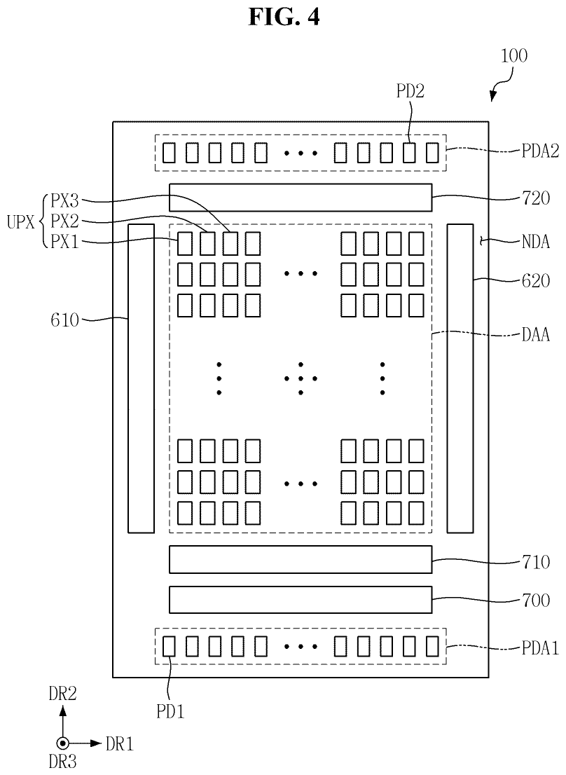

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a common voltage VSS, a driving voltage VDD, and an initialization voltage VINT and supply them to the display panel 100. The common voltage VSS, the driving voltage VDD, and the initialization voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, digital video data DATA, and the data timing control signal DCS of the timing control circuit 400 may be supplied to the display panel 100 through the circuit board 300. In addition, the common voltage VSS, the driving voltage VDD, and the initialization voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS. Each of the timing control circuit 400 and the power supply circuit 500 may be located between the data driver 700 and the first pad portion PDA1 (see FIG. 4).

FIG. 3 is an equivalent circuit diagram of a first pixel according to some embodiments. Although FIG. 3 illustrates various components in a pixel circuit according to some embodiments, embodiments according to the present disclosure are not limited thereto, and according to some embodiments, the pixel circuit may include additional components or fewer components without departing from the spirit and scope of embodiments according to the present disclosure.

Referring to FIG. 3, the first pixel PX1 may be connected to the write scan line GWL, the control scan line GCL, the bias scan line EBL, the first emission control line EL1, the second emission control line EL2, and the data line DL. In addition, the first pixel PX1 may be connected to a common voltage line VSL to which the common voltage VSS corresponding to a low potential voltage is applied, a driving voltage line VDL to which the driving voltage VDD corresponding to a high potential voltage is applied, and an initialization voltage line VIL to which the initialization voltage VINT is applied. That is, the common voltage line VSL may be a low potential voltage line, the driving voltage line VDL may be a high potential voltage line, and the initialization voltage line VIL may be an initialization voltage line. In this case, the common voltage VSS may be lower than the initialization voltage VINT. The driving voltage VDD may be higher than the initialization voltage VINT.

The first pixel PX1 includes a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current. The light-emitting element LE may be located between the fourth transistor T4 and the common voltage line VSL. The first electrode of the light-emitting element LE may be connected to the drain electrode of the fourth transistor T4, and the second electrode thereof may be connected to the common voltage line VSL. The first electrode of the light-emitting element LE may be an anode electrode, and the second electrode of the light-emitting element LE may be a cathode electrode.

The light-emitting element LE may be an organic light-emitting diode including a first electrode, a second electrode, and an organic light-emitting layer located between the first electrode and the second electrode, but embodiments according to the present disclosure are not limited thereto. For example, the light-emitting element LE may be an inorganic light-emitting element including a first electrode, a second electrode, and an inorganic semiconductor located between the first electrode and the second electrode, in which case the light-emitting element LE may be a micro light-emitting diode.

The first transistor T1 may be a driving transistor that controls a source-drain current (hereinafter referred to as “driving current”) flowing between the source electrode and the drain electrode thereof according to a voltage applied to the gate electrode thereof. The first transistor T1 includes a gate electrode connected to a first node N1, a source electrode connected to the drain electrode of a sixth transistor T6, and a drain electrode connected to a second node N2.

A second transistor T2 may be located between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be located between the first node N1 and the second node N2. The third transistor T3 is turned on by the write control signal of the write control line GCL to connect the first node N1 to the second node N2. For this reason, because the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

The fifth transistor T5 may be located between the third node N3 and the initialization voltage line VIL. The fifth transistor T5 is turned on by the bias scan signal of the bias scan line EBL to connect the third node N3 to the initialization voltage line VIL. Accordingly, the initialization voltage VINT of the initialization voltage line VIL may be applied to the first electrode of the light-emitting element LE. The fifth transistor T5 includes a gate electrode connected to the bias scan line EBL, a source electrode connected to the third node N3, and a drain electrode connected to the initialization voltage line VIL.

The sixth transistor T6 may be located between the source electrode of the first transistor T1 and the driving voltage line VDL. The sixth transistor T6 is turned on by the second emission control signal of the second emission control line EL2 to connect the source electrode of the first transistor T1 to the driving voltage line VDL. Accordingly, the driving voltage VDD of the driving voltage line VDL may be applied to the source electrode of the first transistor T1. The sixth transistor T6 includes a gate electrode connected to the second emission control line EL2, a source electrode connected to the driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the driving voltage line VDL. The second capacitor CP2 includes one electrode connected to the gate electrode of the first transistor T1 and the other electrode connected to the driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but embodiments according to the present disclosure are not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first pixel PX1 includes the six transistors T1 to T6 and the two capacitors C1 and C2, the equivalent circuit diagram of the first pixel PX1 is not limited to the example shown in FIG. 3. For example, the number of the transistors and the number of the capacitors of the first pixel PX1 are not limited to the example shown in FIG. 3.

In addition, the equivalent circuit diagram of a second pixel PX2 and the equivalent circuit diagram of a third pixel PX3 may be the same (or substantially the same) as the equivalent circuit diagram of the first pixel PX1 described in conjunction with FIG. 3. Thus, in the present specification, description of the equivalent circuit diagram of the second pixel PX2 and the equivalent circuit diagram of the third pixel PX3 will be omitted.

FIG. 4 is a layout diagram illustrating an example of a display panel according to some embodiments.

Referring to FIG. 4, the display area DAA of the display panel 100 according to some embodiments includes the plurality of pixels PX arranged in a matrix form. The non-display area NDA of the display panel 100 according to some embodiments includes the scan driver 610, the emission driver 620, the data driver 700, a first distribution circuit 710, a second distribution circuit 720, the first pad portion PDA1, and a second pad portion PDA2.

The scan driver 610 may be located on the first side of the display area DAA, and the emission driver 620 may be located on the second side of the display area DAA. For example, the scan driver 610 may be located on one side of the display area DAA in the first direction DR1, and the emission driver 620 may be located on the other side of the display area DAA in the first direction DR1. That is, the scan driver 610 may be located on the left side of the display area DAA, and the emission driver 620 may be located on the right side of the display area DAA. However, embodiments according to the present disclosure are not limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on the third side of the display area DAA. For example, the first pad portion PDA1 may be located on one side of the display area DAA in the second direction DR2.

The first pad portion PDA1 may be located outside the data driver 700 in the second direction DR2. That is, the first pad portion PDA1 may be located closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA.

The second distribution circuit 720 may be located on the fourth side of the display area DAA of the display panel 100. For example, the second distribution circuit 720 may be located on the other side of the display area DAA in the second direction DR2. That is, the second distribution circuit 720 may be located on the upper side of the display area DAA.

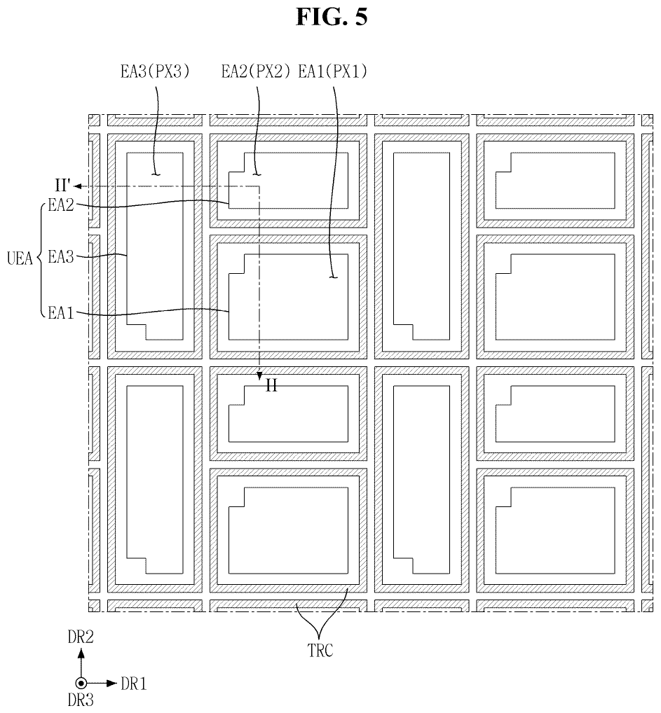

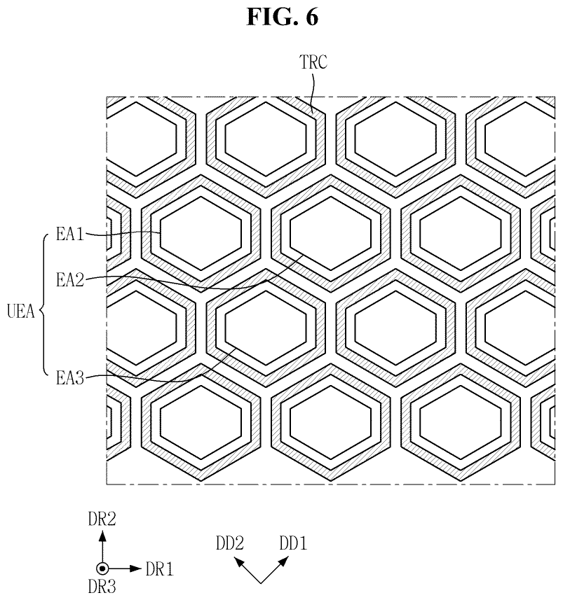

FIGS. 5 and 6 are layout diagrams illustrating embodiments of the display area of FIG. 4.

Referring to FIGS. 5 and 6, each of the plurality of unit pixels UPX includes a first emission area EA1 as an emission area of the first pixel PX1, a second emission area EA2 as an emission area of the second pixel PX2, and a third emission area EA3 as an emission area of the third pixel PX3. In other words, the unit pixel UPX may include a unit emission area UEA, and the unit emission area UEA includes the first emission area EA1, the second emission area EA2, and the third emission area EA3 described above.

Referring to FIGS. 5 and 6, each of the plurality of pixels PX includes the first emission area EA1 as an emission area of the first pixel PX1, the second emission area EA2 as an emission area of the second pixel PX2, and the third emission area EA3 as an emission area of the third pixel PX3.

Each of the first emission area EA1, the second emission area EA2, and the third emission area EA3 may have a polygonal, circular, elliptical, or atypical shape in a plan view.

The maximum length of the first emission area EA1 in the first direction DR1 may be less than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be the same (or substantially the same).

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be greater than the maximum length of the third emission area EA3 in the second direction DR2. The maximum length of the third emission area EA3 in the second direction DR2 may be less than the maximum length of the second emission area EA2 in the second direction DR2.

The first emission area EA1, the second emission area EA2, and the third emission area EA3 may have, in plan view, a hexagonal shape formed of six straight lines as shown in FIGS. 5 and 6, but embodiments according to the present disclosure are not limited thereto. The first emission area EA1, the second emission area EA2, and the third emission area EA3 may have a polygonal shape other than a hexagon, a circular shape, an elliptical shape, or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of 370 nanometers (nm) to 460 nm (or about 370 nm to about 460 nm), the green wavelength band may be a wavelength band of light whose main peak wavelength is in the range of 480 nm to 560 nm (or about 480 nm to about 560 nm), and the red wavelength band may be a wavelength band of light whose main peak wavelength is in the range of 600 nm to 750 nm (or about 600 nm to about 750 nm).

It is illustrated in FIGS. 5 and 6 that each of the plurality of pixels PX includes three emission areas EA1, EA2, and EA3, but embodiments according to the present disclosure are not limited thereto. That is, each of the plurality of pixels PX may include four emission areas.

In addition, the layout of the emission areas of the plurality of pixels PX is not limited to those illustrated in FIGS. 5 and 6. For example, the emission areas of the plurality of pixels PX may be arranged in a stripe structure in which the emission areas are arranged in the first direction DR1, a PenTile® structure or arrangement in which the emission areas are arranged in a diamond shape, or a hexagonal structure in which the emission areas having, in a plan view, a hexagonal shape are arranged as shown in FIG. 6.

FIG. 7 is a cross-sectional view illustrating an example of a display panel taken along the line II-II′ of FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be located on the semiconductor substrate SSUB. The first semiconductor insulating film SINS1 may be formed of silicon carbonitride (SiCN) or a silicon oxide (SiOx)-based inorganic film, but embodiments according to the present disclosure are not limited thereto.

A second semiconductor insulating film SINS2 may be located on the first semiconductor insulating film SINS1. The second semiconductor insulating film SINS2 may be formed of a silicon oxide (SiOx)-based inorganic film, but embodiments according to the present disclosure are not limited thereto.

The plurality of contact terminals CTE may be located on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be located on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but embodiments according to the present disclosure are not limited thereto.

The semiconductor substrate SSUB may be replaced with a glass substrate or a polymer resin substrate such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light-emitting element backplane EBP includes a plurality of conductive layers ML1 to ML8, a plurality of vias VA1 to VA9, and a plurality of insulating films INS1 to INS9. In addition, the light-emitting element backplane EBP includes a plurality of insulating films INS1 to INS9 located between the first to eighth conductive layers ML1 to ML8.

The first to eighth conductive layers ML1 to ML8 serve to connect the plurality of contact terminals CTE exposed from the semiconductor backplane SBP to thereby implement the circuit of the first pixel PX1 shown in FIG. 3. For example, the first to sixth transistors T1 to T6 are merely formed in the semiconductor backplane SBP, and the connection of the first to sixth transistors T1 to T6 and the first and second capacitors CP1 and CP2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light-emitting element LE is also accomplished through the first to eighth conductive layers ML1 to ML8.

The first insulating film INS1 may be located on the semiconductor backplane SBP. Each of the first vias VA1 may penetrate the first insulating film INS1 and be connected to the contact terminal CTE exposed from the semiconductor backplane SBP. Each of the first conductive layers ML1 may be located on the first insulating film INS1 and may be connected to the first via VA1.

The second insulating film INS2 may be located on the first insulating film INS1 and the first conductive layers ML1. Each of the second vias VA2 may penetrate the second insulating film INS2 and be connected to the exposed first conductive layer ML1. Each of the second conductive layers ML2 may be located on the second insulating film INS2 and may be connected to the second via VA2.

The third insulating film INS3 may be located on the second insulating film INS2 and the second conductive layers ML2. Each of the third vias VA3 may penetrate the third insulating film INS3 and be connected to the exposed second conductive layer ML2. Each of the third conductive layers ML3 may be located on the third insulating film INS3 and may be connected to the third via VA3.

A fourth insulating film INS4 may be located on the third insulating film INS3 and the third conductive layers ML3. Each of the fourth vias VA4 may penetrate the fourth insulating film INS4 and be connected to the exposed third conductive layer ML3. Each of the fourth conductive layers ML4 may be located on the fourth insulating film INS4 and may be connected to the fourth via VA4.

A fifth insulating film INS5 may be located on the fourth insulating film INS4 and the fourth conductive layers ML4. Each of the fifth vias VA5 may penetrate the fifth insulating film INS5 and be connected to the exposed fourth conductive layer ML4. Each of the fifth conductive layers ML5 may be located on the fifth insulating film INS5 and may be connected to the fifth via VA5.

A sixth insulating film INS6 may be located on the fifth insulating film INS5 and the fifth conductive layers ML5. Each of the sixth vias VA6 may penetrate the sixth insulating film INS6 and be connected to the exposed fifth conductive layer ML5. Each of the sixth conductive layers ML6 may be located on the sixth insulating film INS6 and may be connected to the sixth via VA6.

A seventh insulating film INS7 may be located on the sixth insulating film INS6 and the sixth conductive layers ML6. Each of the seventh vias VA7 may penetrate the seventh insulating film INS7 and be connected to the exposed sixth conductive layer ML6. Each of the seventh conductive layers ML7 may be located on the seventh insulating film INS7 and may be connected to the seventh via VA7.

An eighth insulating film INS8 may be located on the seventh insulating film INS7 and the seventh conductive layers ML7. Each of the eighth vias VA8 may penetrate the eighth insulating film INS8 and be connected to the exposed seventh conductive layer ML7. Each of the eighth conductive layers ML8 may be located on the eighth insulating film INS8 and may be connected to the eighth via VA8.

The first to eighth conductive layers ML1 to ML8 and the first to eighth vias VA1 to VA8 may be formed of the same (or substantially the same) material. The first to eighth conductive layers ML1 to ML8 and the first to eighth vias VA1 to VA8 may be formed of any one of copper (Cu), aluminum (AI), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of the same (or substantially the same) material. First to eighth insulating films INS1 to INS8 may be formed of a silicon oxide (SiOx)-based inorganic film, but embodiments according to the present disclosure are not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be the same (or substantially the same). For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be the same (or substantially the same). For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating film INS9 may be located on the eighth insulating film INS8 and the eighth conductive layer ML8. The ninth insulating film INS9 may be formed of a silicon oxide (SiOx)-based inorganic film, but embodiments according to the present disclosure are not limited thereto.

Each of the ninth vias VA9 may penetrate the ninth insulating film INS9 and be connected to the exposed eighth conductive layer ML8. The ninth vias VA9 may be formed of any one of copper (Cu), aluminum (AI), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16500 Å.

The display element layer EML may be located on the light-emitting element backplane EBP. The display element layer EML may include light-emitting elements LE each including a first electrode AND, a light-emitting stack ES, and a second electrode CAT; a reflective electrode layer RL; tenth and eleventh insulating films INS10 and INS11; a tenth via VA10; a pixel defining film PDL; and a plurality of trenches TRC.

The reflective electrode layer RL may be located on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7.

Each of the first reflective electrodes RL1 may be located on the ninth insulating film INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be located on the first reflective electrode RL1. The second reflective electrodes RL2 may be formed of any one of copper (Cu), aluminum (AI), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be located on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

Each of the fourth reflective electrodes RL4 may be located on the third reflective electrode RL3. The fourth reflective electrodes RL4 may be formed of any one of copper (Cu), aluminum (AI), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Because the second reflective electrode RL2 is an electrode that reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be located on the ninth insulating film INS9. The tenth insulating film INS10 may be located between the reflective electrode layers RL adjacent to each other in a horizontal direction. The tenth insulating film INS10 may be located on the reflective electrode layer RL in the third pixel PX3. The tenth insulating film INS10 may be formed of a silicon oxide (SiOx)-based inorganic film, but embodiments according to the present disclosure are not limited thereto.

The eleventh insulating film INS11 may be located on the tenth insulating film INS10 and the reflective electrode layer RL. The eleventh insulating film INS11 may be formed of a silicon oxide (SiOx)-based inorganic film, but embodiments according to the present disclosure are not limited thereto. The tenth insulating film INS10 and the eleventh insulating film INS11 may be an optical auxiliary layer through which light reflected by the reflective electrode layer RL passes, among light emitted from the light-emitting elements LE.

In order to match the resonance distance of the light emitted from the light-emitting elements LE in at least one of the first pixel PX1, the second pixel PX2, and the third pixel PX3, a thickness of the eleventh insulating film INS11 in the first pixel PX1, the second pixel PX2, and the third pixel PX3 may be different. For example, the thickness of the eleventh insulating film INS11 in the third pixel PX3 may be larger than the thickness of the eleventh insulating film INS11 in the second pixel PX2 and the thickness of the eleventh insulating film INS11 in the first pixel PX1, and the thickness of the eleventh insulating film INS11 in the second pixel PX2 may be larger than the thickness of the eleventh insulating film INS11 in the first pixel PX1. In another embodiment, the tenth insulating film INS10, or the eleventh insulating film INS11 may not be located under the first electrode AND of the first pixel PX1. The first electrode AND of the first pixel PX1 may be directly located on the reflective electrode layer RL. The eleventh insulating film INS11 may be located under the first electrode AND of the second pixel PX2. The tenth insulating film INS10 and the eleventh insulating film INS11 may be located under the first electrode AND of the third pixel PX3.

In summary, the distance between the first electrode AND and the reflective electrode layer RL may be different in the first pixel PX1, the second pixel PX2, and the third pixel PX3. In order to adjust the distance from the reflective electrode layer RL to the first electrode AND according to the main wavelength of the light emitted from each of the first pixel PX1, the second pixel PX2, and the third pixel PX3, the thickness of the eleventh insulating film INS11 in the first pixel PX1, the second pixel PX2, and the third pixel PX3 may be adjusted, or the presence or absence of the tenth insulating film INS10 and the eleventh insulating film INS11 may be set in each of the first pixel PX1, the second pixel PX2, and the third pixel PX3. For example, it is illustrated in FIG. 7 that the distance between the first electrode AND and the reflective electrode layer RL in the third pixel PX3 is larger than the distance between the first electrode AND and the reflective electrode layer RL in the second pixel PX2 and the distance between the first electrode AND and the reflective electrode layer RL in the first pixel PX1, and the distance between the first electrode AND and the reflective electrode layer RL in the second pixel PX2 is larger than the distance between the first electrode AND and the reflective electrode layer RL in the first pixel PX1, but embodiments according to the present disclosure are not limited thereto.

In addition, although the tenth insulating film INS10 and the eleventh insulating film INS11 are illustrated in the present disclosure, a twelfth insulating film located under the first electrode AND of the first pixel PX1 may be added. In this case, the eleventh insulating film INS11 and a twelfth insulating film may be located under the first electrode AND of the second pixel PX2, and the tenth insulating film INS10, the eleventh insulating film INS11, and the twelfth insulating film may be located under the first electrode AND of the third pixel PX3.

Each of the tenth vias VA10 may penetrate the eleventh insulating film INS11 in the first pixel PX1, the second pixel PX2 and the third pixel PX3 and may be connected to the exposed reflective electrode layer RL. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second pixel PX2 may be less than the thickness of the tenth via VA10 in the third pixel PX3.

The first electrode AND of each of the light-emitting elements LE may be located on the eleventh insulating film INS11 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light-emitting elements LE may be titanium nitride (TiN).

The pixel defining film PDL may be located on a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3.

The first emission area EA1 may be defined as an area in which the first electrode AND, the light-emitting stack ES, and the second electrode CAT are sequentially stacked in the first pixel PX1 to emit light. The second emission area EA2 may be defined as an area in which the first electrode AND, the light-emitting stack ES, and the second electrode CAT are sequentially stacked in the second pixel PX2 to emit light. The third emission area EA3 may be defined as an area in which the first electrode AND, the light-emitting stack ES, and the second electrode CAT are sequentially stacked in the third pixel PX3 to emit light.

The pixel defining film PDL may include first to third pixel defining films PDL1, PDL2, and PDL3. The first pixel defining film PDL1 may be located on the edge of the first electrode AND of each of the light-emitting elements LE, the second pixel defining film PDL2 may be located on the first pixel defining film PDL1, and the third pixel defining film PDL3 may be located on the second pixel defining film PDL2. The first pixel defining film PDL1, the second pixel defining film PDL2, and the third pixel defining film PDL3 may be formed of a silicon oxide (SiOx)-based inorganic film, but embodiments according to the present disclosure are not limited thereto. The first pixel defining film PDL1, the second pixel defining film PDL2, and the third pixel defining film PDL3 may each have a thickness of 500 Å (or about 500 Å).

When the first pixel defining film PDL1, the second pixel defining film PDL2, and the third pixel defining film PDL3 are formed as one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

Each of the plurality of trenches TRC may penetrate the first pixel defining film PDL1, the second pixel defining film PDL2, and the third pixel defining film PDL3. Furthermore, each of the plurality of trenches TRC may penetrate the eleventh insulating film INS11. In addition, each of the plurality of trenches TRC may also be further formed so that the tenth insulating film INS10 may be partially recessed at each of the plurality of trenches TRC.

At least one trench TRC may be located between the neighboring pixels PX1, PX2, and PX3. Although FIG. 7 illustrates that two trenches TRC are located between adjacent pixels PX1, PX2, and PX3, the embodiments of the present disclosure are not limited thereto.

The light-emitting stack ES may include a plurality of stack layers. FIG. 7 illustrates that the light-emitting stack ES has a three-tandem structure including a first stack layer IL1, a second stack layer IL2, and a third stack layer IL3, but the embodiments of the present disclosure are not limited thereto. For example, the light-emitting stack ES may have a two-tandem structure including two intermediate layers.

In the three-tandem structure, the light-emitting stack ES may have a tandem structure including a plurality of stack layers IL1, IL2, and IL3 that emit different lights. For example, the light-emitting stack ES may include the first stack layer IL1 that emits light of the first color, the second stack layer IL2 that emits light of the second color, and the third stack layer IL3 that emits light of the third color. The first stack layer IL1, the second stack layer IL2, and the third stack layer IL3 may be sequentially stacked.

The first stack layer IL1 may have a structure in which a first hole transport layer, a first organic light-emitting layer that emits light of the first color, and a first electron transport layer are sequentially stacked. The second stack layer IL2 may have a structure in which a second hole transport layer, a second organic light-emitting layer that emits light of the second color, and a second electron transport layer are sequentially stacked. The third stack layer IL3 may have a structure in which a third hole transport layer, a third organic light-emitting layer that emits light of the third color, and a third electron transport layer are sequentially stacked.

A first charge generation layer for supplying holes to the second stack layer IL2 and supplying electrons to the first stack layer IL1 may be located between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying holes to the third stack layer IL3 and supplying electrons to the second stack layer IL2 may be located between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be located on the first electrodes AND and the pixel defining film PDL, and may be located on the bottom surface of each trench TRC. Due to the trench TRC, the first stack layer IL1 may be cut off between the neighboring pixels PX1, PX2, and PX3. The second stack layer IL2 may be located on the first stack layer IL1. Due to the trench TRC, the second stack layer IL2 may be cut off between the neighboring pixels PX1, PX2, and PX3. A cavity ESS or an empty space may be located between the first stack layer IL1 and the second stack layer IL2. The third stack layer IL3 may be located on the second stack layer IL2. The third stack layer IL3 is not cut off by the trench TRC and may be arranged to cover the second stack layer IL2 in each of the trenches TRC. That is, in the three-tandem structure, each of the plurality of trenches TRC may be a structure for cutting off the first to second stack layers IL1 and IL2, the first charge generation layer, and the second charge generation layer of the display element layer EML between the pixels PX1, PX2, and PX3 adjacent to each other. In addition, in the two-tandem structure, each of the trenches TRC may be a structure for cutting off the charge generation layer located between a lower intermediate layer and an upper intermediate layer, and the lower intermediate layer.

In order to stably cut off the first and second stack layers IL1 and IL2 of the display element layer EML between adjacent pixels PX1, PX2, and PX3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first and second stack layers IL1 and IL2 of the display element layer EML between the neighboring pixels PX1, PX2, and PX3, another structure may exist instead of the trench TRC. For example, instead of the trench TRC, a reverse tapered partition wall may be located on the pixel defining film PDL.

The number of the stack layers IL1, IL2, and IL3 that emit different lights is not limited to that shown in FIG. 7. For example, the light-emitting stack ES may include two intermediate layers. In this case, one of the two intermediate layers may be the same (or substantially the same) as the first stack layer IL1, and the other may include a second hole transport layer, a second organic light-emitting layer, a third organic light-emitting layer, and a second electron transport layer. In this case, a charge generation layer for supplying electrons to one intermediate layer and supplying holes to the other intermediate layer may be located between the two intermediate layers.

In addition, FIG. 7 illustrates that the first to third stack layers IL1, IL2, and IL3 are all located in the first emission area EA1, the second emission area EA2, and the third emission area EA3, but the embodiments of the present disclosure are not limited thereto. For example, the first stack layer IL1 may be located in the first emission area EA1, and may be omitted from the second emission area EA2 and the third emission area EA3. Furthermore, the second stack layer IL2 may be located in the second emission area EA2 and may be omitted from the first emission area EA1 and the third emission area EA3. Further, the third stack layer IL3 may be located in the third emission area EA3 and may be omitted from the first emission area EA1 and the second emission area EA2. In this case, first to third color filters CF1, CF2, and CF3 of the optical layer OPL may be omitted.

The second electrode CAT may be located on the third stack layer IL3. The second electrode CAT may be located on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be relatively improved in each of the first to third pixels PX1, PX2, and PX3 due to a micro-cavity effect.

The encapsulation layer TFE may be located on the display element layer EML. The encapsulation layer TFE may include at least one inorganic film TFE1 and TFE2 to reduce or prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be located on the second electrode CAT. The first encapsulation inorganic film TFE1 may be formed as a multilayer in which one or more inorganic films selected from silicon nitride (SiNx), silicon oxy nitride (SiON), and silicon oxide (SiOx) are alternately stacked. The first encapsulation inorganic film TFE1 may be formed by a chemical vapor deposition (CVD) process.

The second encapsulation inorganic film TFE2 may be located on the first encapsulation inorganic film TFE1. The second encapsulation inorganic film TFE2 may be formed of titanium oxide (TiOx) or aluminum oxide (AIOx), but embodiments according to the present disclosure are not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

An organic film APL may be a layer for increasing the interfacial adhesion between the encapsulation layer TFE and the optical layer OPL. The organic film APL may be an organic film such as acrylic resin, epoxy resin, phenolic resin, polyamide resin, or polyimide resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the organic film APL.

The first color filter CF1 may overlap the first emission area EA1 of the first pixel PX1. The first color filter CF1 may transmit light of the first color, i.e., light of a blue wavelength band. The blue wavelength band may be 370 nm to 460 nm (or about 370 nm to about 460 nm). Thus, the first color filter CF1 may transmit light of the first color among light emitted from the first emission area EA1.

The second color filter CF2 may overlap the second emission area EA2 of the second pixel PX2. The second color filter CF2 may transmit light of the second color, i.e., light of a green wavelength band. The green wavelength band may be in a range of 480 nm to 560 nm (or about 480 nm to about 560 nm). Thus, the second color filter CF2 may transmit light of the second color among light emitted from the second emission area EA2.

The third color filter CF3 may overlap the third emission area EA3 of the third pixel PX3. The third color filter CF3 may transmit light of the third color, i.e., light of a red wavelength band. The red wavelength band may be in a range of 600 nm to 750 nm (or about 600 nm to about 750 nm). Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be located on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be located on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but embodiments according to the present disclosure are not limited thereto. However, when visibility degradation caused by reflection of external light is sufficiently overcome by the first to third color filters CF1, CF2, and CF3, the polarizing plate POL may be omitted.

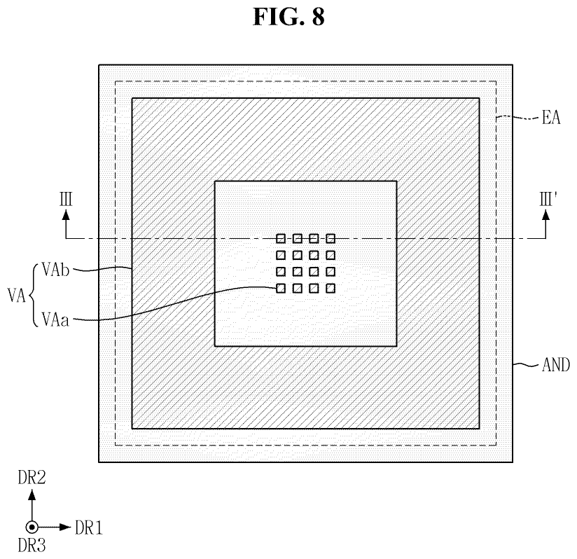

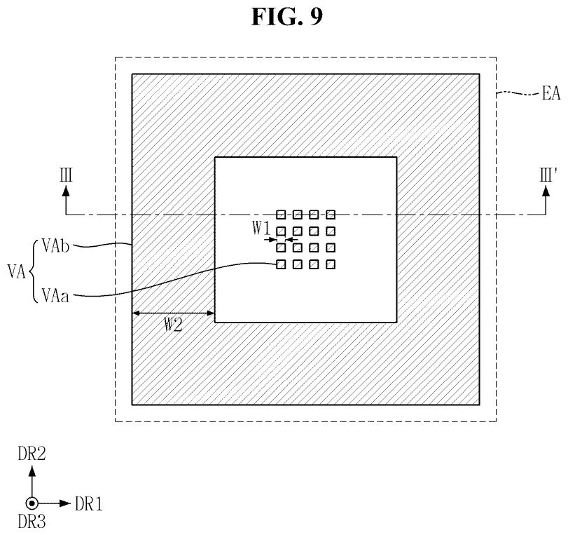

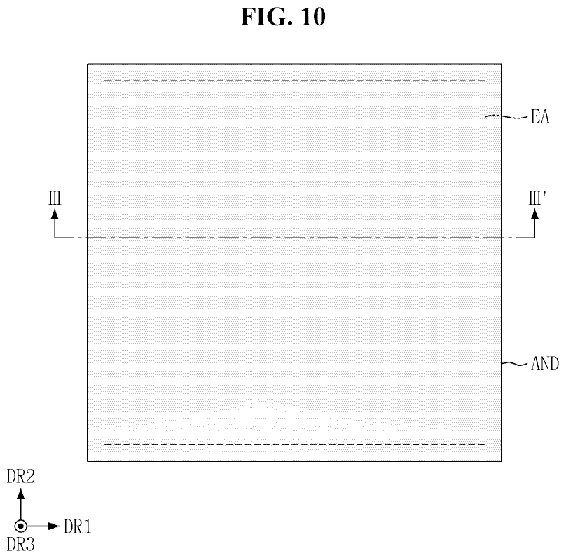

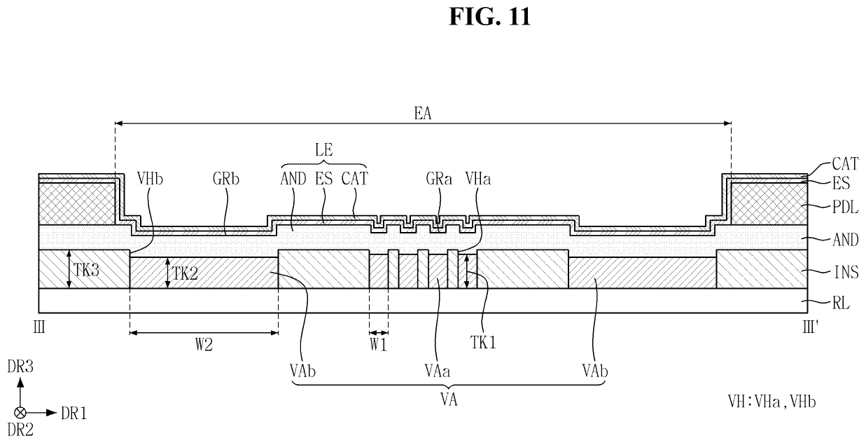

FIG. 8 is a plan view of the display device 10 according to some embodiments, FIG. 9 is a diagram illustrating a via VA and an emission area EA of FIG. 8, FIG. 10 is a diagram illustrating a first electrode AND and the emission area EA of FIG. 8, and FIG. 11 is a cross-sectional view taken along the line II-II′ of FIG. 8.

As shown in FIGS. 8 to 11, the display device 10 according to some embodiments may include a reflective electrode layer RL, an insulating film INS, the via VA, the light-emitting element LE, and the pixel defining film PDL. Here, the light-emitting element LE may include the first electrode AND, the light-emitting stack ES, and the second electrode CAT.

Because the reflective electrode layer RL in FIG. 11 is the same as the reflective electrode layer RL in FIG. 7 described above, refer to the above description of the reflective electrode layer RL in FIG. 7 for the reflective electrode layer RL in FIG. 11.

The insulating film INS may be located on the reflective electrode layer RL. The insulating film INS may be made of the same material as the eleventh insulating film INS11 of FIG. 7 described above. The insulating film INS may have a via hole VH. The via hole VH may be located in the emission area EA. In other words, the via hole VH may overlap the emission area EA. For example, in a plan view, the entire via hole VH may overlap the emission area EA. The via hole VH may include a central via hole VHa that penetrates the insulating film INS at the center of the emission area EA, and an outer via hole VHb that penetrates the insulating film INS at the edge of the emission area EA. Here, the central via hole VHa may be plural in number. For example, the via hole VH may include a plurality of central via holes VHa.

The via VA may be located in the emission area EA. In other words, the via VA may overlap the emission area EA. For example, the entire via VA may overlap the emission area EA. The via VA may be located in the via hole VH of the insulating film INS in the emission area EA. For example, the via VA may be located in the central via holes VHa and the outer via hole VHb of the insulating film INS. The via VA may be connected to the reflective electrode layer RL through the via hole VH of the insulating film INS. The via VA may include the same material as the tenth via VA10 of FIG. 7 described above.

The via VA may include a central metal portion VAa and an outer metal portion VAb, as in the example shown in FIGS. 8, 9, and 11. The central metal portion VAa may be located in the central via hole VHa, and the outer metal portion VAb may be located in the outer via hole VHb.

The central metal portion VAa may be located at the center of the emission area EA. In other words, the central metal portion VAa may overlap the center of the emission area EA. The central metal portion VAa may be plural in number. For example, the via VA may include a plurality of central metal portions VAa. As in the example shown in FIG. 9, the plurality of central metal portions VAa may be arranged along the first direction DR1 and the second direction DR2. The plurality of central metal portions VAa may be arranged to be spaced apart from each other. For example, the central metal portions VAa adjacent in the first direction DR1 may be spaced apart from each other in the first direction DR1, whereas the central metal portions VAa adjacent in the second direction DR2 may be spaced apart from each other in the second direction DR2. In other words, the plurality of central metal portions VAa may be spaced apart from each other in the first direction DR1 or the second direction DR2 so as not to be connected to each other.

The outer metal portion VAb may be arranged along the edge of the emission area EA. In other words, the outer metal portion VAb may overlap the edge of the emission area EA. The outer metal portion VAb may surround the central metal portions VAa, as in the example shown in FIGS. 8 and 9. For example, the outer metal portion VAb may have a closed curve shape surrounding the central metal portions VAa. The outer metal portion VAb may be arranged to be spaced apart from the central metal portions VAa so that the central metal portions VAa are not connected to each other.

At least either the central metal portions VAa or the outer metal portion VAb may be connected to the reflective electrode layer RL. For example, both the central metal portions VAa and the outer metal portion VAb may be connected to the reflective electrode layer RL.

As in the example shown in the plan view of FIG. 9, the central metal portion VAa and the outer metal portion VAb may have different areas. For example, the area of the outer metal portion VAb may be larger than the total area of the central metal portions VAa. Here, the area may mean the product of the size in the first direction DR1 and the size in the second direction DR2.

As in the example shown in the cross-sectional view of FIG. 11, the central metal portion VAa and the outer metal portion VAb may have different widths (W1<W2). For example, the width W2 of the outer metal portion VAb may be greater than the width W1 of the central metal portion VAa. Here, the width may mean the size in the first direction DR1 (or the second direction DR2).

As in the example shown in the cross-sectional view of FIG. 11, the central metal portion VAa and the outer metal portion VAb may have different thicknesses (TK1>TK2). For example, the thickness TK1 of the central metal portion VAa may be greater than the thickness TK2 of the outer metal portion VAb. Here, the thickness may mean the size in the third direction DR3.

As in the example shown in the cross-sectional view of FIG. 11, the thickness of the via VA and the thickness of the above-described insulating film INS may be different (TK2<TK1<TK3). For example, the thickness TK3 of the insulating film INS may be greater than the thickness TK1 or TK2 of the via VA. In other words, the thickness TK3 of the insulating film INS may be greater than the thickness TK1 of the central metal portion VAa. Additionally, the thickness TK3 of the insulating film INS may be greater than the thickness TK2 of the outer metal portion VAb.

The first electrode AND may be located on the insulating film INS and the via VA. For example, the first electrode AND may be located on the insulating film INS, the plurality of central metal portions VAa, and the outer metal portion VAb. The first electrode AND and the via VA may be electrically connected. For example, the first electrode AND and the central metal portions VAa may be electrically connected, and the first electrode AND and the outer metal portion VAb may be electrically connected. The central metal portions VAa and the outer metal portion VAb may be electrically connected to each other through the first electrode AND. The central metal portions VAa may be electrically connected to each other through the first electrode AND. The first electrode AND of FIG. 11 may be made of the same material as the first electrode AND of FIG. 7 described above.

The first electrode AND may overlap the via VA. Due to the aforementioned thickness difference between the insulating film INS and the via VA, the first electrode AND overlapping the insulating film INS and the via VA may have a stepped portion. For example, the first electrode AND may have an uneven surface shape. In other words, the top surface of the first electrode AND may have a protrusion portion protruding in the third direction DR3 and a recess portion recessed in the reverse direction of the third direction DR3 (hereinafter, referred to as reverse third direction). Here, the recess portions of the first electrode AND may include a central groove GRa and an outer groove GRb of the first electrode AND, which will be described later.

As stated above, the first electrode AND may overlap the via VA, and the first electrode AND may have at least one central groove GRa in the area overlapping the central metal portion VAa. For example, the center of the first electrode AND may have at least one central groove GRa recessed in the reverse third direction. The central groove GRa may be formed due to the thickness difference between the insulating film INS and the central metal portion VAa described above. The width of the central groove GRa may be approximately the same as the width W1 of the central metal portion VAa. For example, the width of the central groove GRa may be equal (or substantially equal) to the width W1 of the central metal portion VAa. Here, in cross-sectional view, the width of the central groove GRa may be, for example, a distance between inner walls on both sides defining the central groove GRa (for example, inner walls on both sides of the central groove GRa, facing in the first direction DR1).

As described above, the first electrode AND may overlap the via VA, and the first electrode AND may have the outer groove GRb in the area overlapping the outer metal portion VAb. For example, the outer portion of the first electrode AND may have the outer groove GRb recessed in the reverse third direction. The outer groove GRb may be formed due to the aforementioned thickness difference between the insulating film INS and the outer metal portion VAb. The width of the outer groove GRb may be approximately the same as the width W2 of the outer metal portion VAb. For example, the width of the outer groove GRb may be equal (or substantially equal) to the width W2 of the outer metal portion VAb. Accordingly, the width of the outer groove GRb may be greater than the width of the central groove GRa. Here, in cross-sectional view, the width of the outer groove GRb may be, for example, a distance between inner walls on both sides defining the outer groove GRb (for example, inner walls on both sides of the outer groove GRb, facing in the first direction DR1).

The pixel defining film PDL may be located on the first electrode AND. For example, the pixel defining film PDL may be located on the edge of the first electrode AND to define the emission area EA. In a plan view, the pixel defining film PDL may surround the via VA. For example, the pixel defining film PDL may surround the plurality of central metal portions VAa and the outer metal portion VAb. In other words, in a plan view, the emission area EA defined by the pixel defining film PDL may surround the plurality of central metal portions VAa and the outer metal portion VAb.

In a plan view, the pixel defining film PDL may surround the via hole VH. For example, the pixel defining film PDL may surround the plurality of central via holes VHa and the outer via hole VHb. The pixel defining film PDL does not overlap the plurality of central metal portions VAa and the outer metal portion VAb. The pixel defining film PDL may have the same structure as the pixel defining film PDL of FIG. 7 described above. For example, the pixel defining film PDL in FIG. 11 may include the first pixel defining film PDL1, the second pixel defining film PDL2, and the third pixel defining film PDL3 sequentially stacked along the third direction DR3. The pixel defining film PDL of FIG. 11 may be made of the same material as the pixel defining film PDL of FIG. 7 described above.

The light-emitting stack ES may be located on the pixel defining film PDL and the first electrode AND. The light-emitting stack ES may be located in the central groove GRa and the outer groove GRb of the first electrode AND, and may also be located on the protrusion portion of the first electrode AND. The light-emitting stack ES of FIG. 11 may have the same structure as the light-emitting stack ES of FIG. 7 described above. For example, the light-emitting stack ES of FIG. 11 may include a first stack layer, a second stack layer, and a third stack layer sequentially stacked along the third direction DR3. The light-emitting stack ES of FIG. 11 may include the same material as the light-emitting stack ES of FIG. 7 described above.

The second electrode CAT may be located on the light-emitting stack ES. The second electrode CAT may include the same material as the second electrode CAT of FIG. 11 described above.

The encapsulation layer TFE, the organic film APL, the optical layer OPL, the cover layer CVL, and the polarizing plate POL of FIG. 7 described above may be located on the second electrode CAT.

Meanwhile, the semiconductor backplane SBP and the light-emitting element backplane EBP of FIG. 7 described above may be located below the reflective electrode layer RL of FIG. 11.

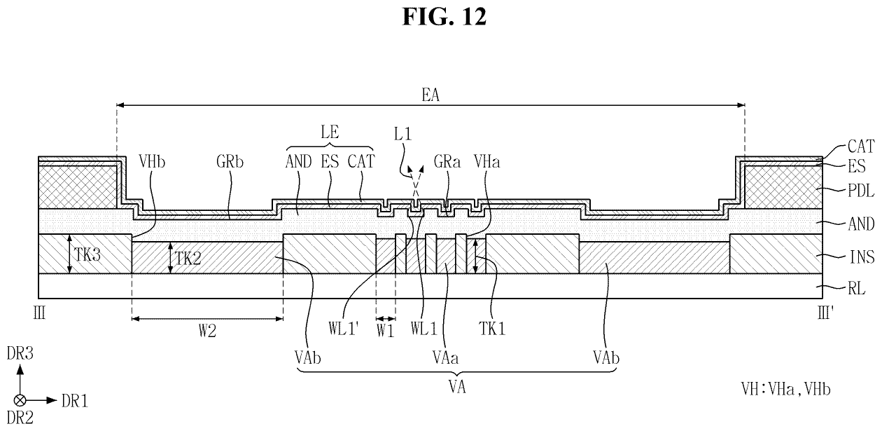

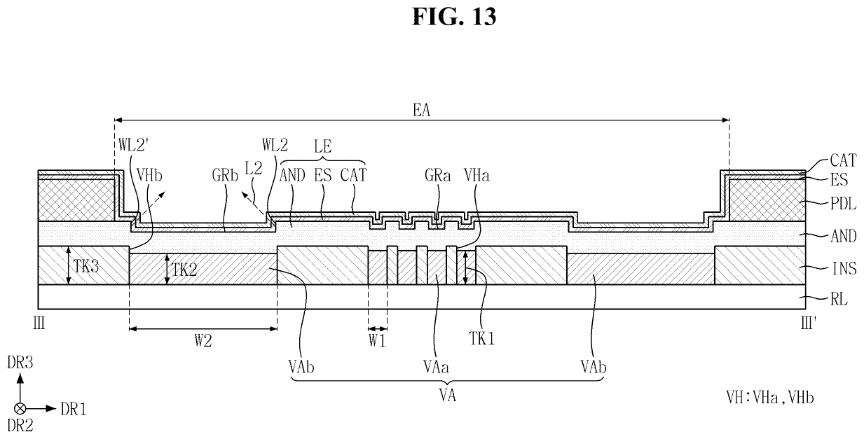

According to some embodiments, because the widths of the central groove GRa and the outer groove GRb of the first electrode AND are different from each other, the concentration of light may be relatively improved at the center of the first electrode AND where the central groove GRa is provided (for example, at the center of the emission area EA), and the luminance of the light may be relatively improved at the outer portion of the first electrode AND where the outer groove GRb is provided (for example, at the edge of the emission area EA). This will be explained in detail with reference to FIGS. 12 and 13 as follows.

FIG. 12 is a diagram for explaining the principle of improvement of the correction light at the center of the first electrode AND in the display device 10 according to some embodiments.

For example, because the central groove GRa has a smaller width than the outer groove GRb, the distance (e.g., W1) between inner walls WL1′ and WL1 on both sides of the central groove GRa is less than the distance (e.g., W2) between inner walls WL2′ and WL2 (see FIG. 13) on both sides of the outer groove GRb. Accordingly, the lights emitted from the light-emitting stack ES and reflected from the inner walls WL1′ and WL1 on both sides of the central groove GRa may intersect more around the central groove GRa. Accordingly, the concentration of light L1 at the center of the emission area EA corresponding to the center of the first electrode AND may be relatively improved.

FIG. 13 is a diagram for explaining the principle of improvement of the correction light at the outer portion of the first electrode AND in the display device 10 according to some embodiments.

For example, because the outer groove GRb has a larger width than the central groove GRa, the distance (e.g., W2) between the inner walls WL2′ and WL2 on both sides of the outer groove GRb is greater than the distance (e.g., W1) between the inner walls WL1 and WL1′ on both sides of the central groove GRa. Accordingly, between the inner walls WL2 and WL2′ on both sides of the outer groove GRb, the inner wall WL2 on one side that is further away from the pixel defining film PDL may be located further away from the pixel defining film PDL. Therefore, the light emitted from the light-emitting stack ES and reflected from the inner wall WL2 on the one side may propagate to the outside without being blocked (or absorbed) by the pixel defining film PDL. Accordingly, the luminance of light L2 at the edge of the emission area EA corresponding to the outer portion of the first electrode AND may increase.

Further, in the display device 10 according to some embodiments, the via VA does not need to overlap the pixel defining film PDL, so the size of the pixel defining film PDL may be set to the minimum regardless of the area of the via VA. In other words, according to some embodiments, the via VA overlaps the opening area (e.g., the emission area EA) of the pixel defining film PDL, thus contributing to forming the central groove GRa and the outer groove GRb in the emission area EA described above. Thus, the via VA does not need to overlap the pixel defining film PDL. Accordingly, the area of the emission area EA may be maximized or improved, and thus the opening ratio of pixels may be relatively improved.

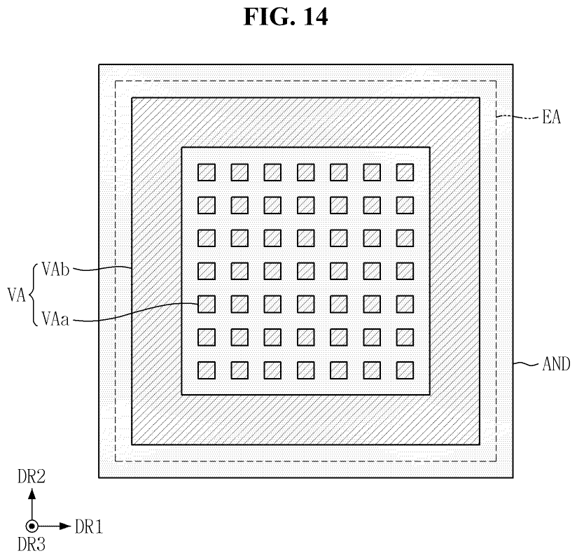

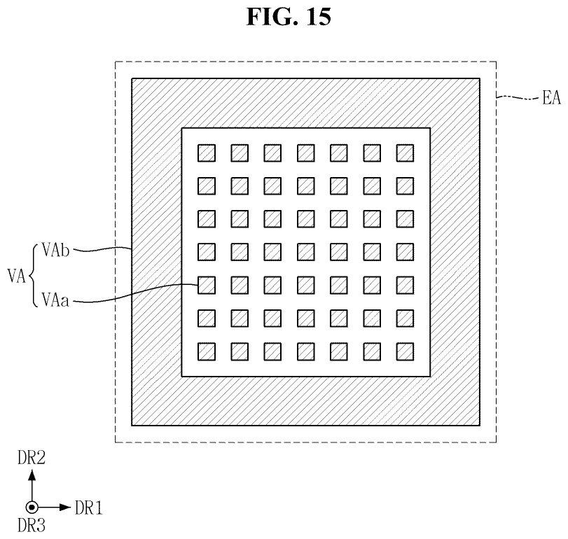

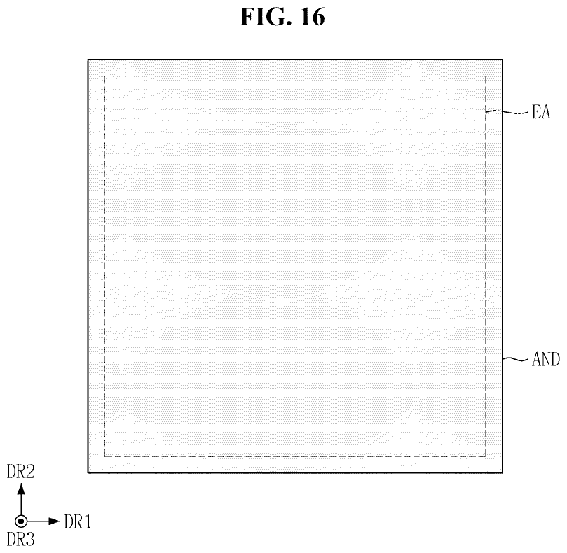

FIG. 14 is a plan view of the display device 10 according to some embodiments, FIG. 15 is a diagram illustrating the via VA and the emission area EA of FIG. 14, and FIG. 16 is a diagram illustrating the first electrode AND and the emission area EA of FIG. 14.

The display device 10 of FIGS. 14 to 16 differs from the above-described display device 10 of FIG. 8 in the number of the central metal portions VAa, and the following description will mainly focus on this difference.

For example, the via VA of the display device 10 in FIGS. 14 to 16 may include forty-nine central metal portions VAa. In other words, while the via VA of the display device 10 in FIG. 8 described above has the sixteen central metal portions VAa, the via VA of the display device 10 in FIG. 14 may have the forty-nine central metal portions VAa in a larger number than that. However, the number of the central metal portions VAa is not limited thereto, and may be modified in various ways.

According to some embodiments, with an increase of the number of the central metal portions VAa, the distance between the central metal portions VAa and the outer metal portion VAb may decrease. For example, the distance between the central metal portions VAa and the outer metal portion VAb of FIG. 14 may be less than the distance between the central metal portions VAa and the outer metal portion VAb of FIG. 8.

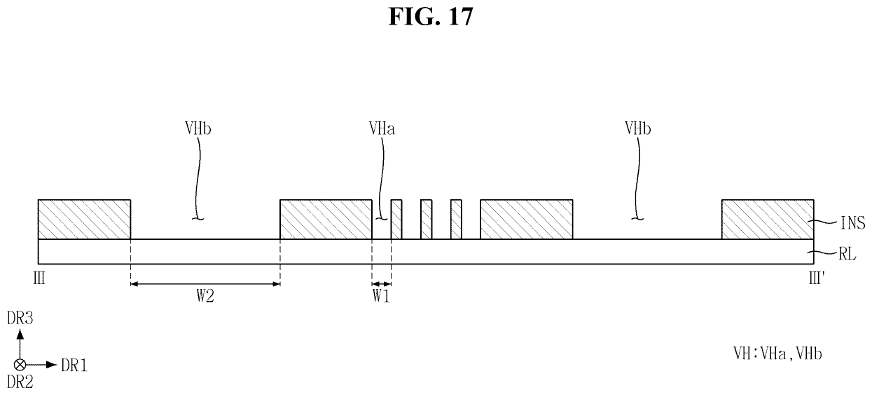

FIGS. 17 to 22 are process cross-sectional views illustrating a method of manufacturing the display device 10 according to some embodiments.

First, as shown in FIG. 17, the insulating film INS may be located on the reflective electrode layer RL. Thereafter, the insulating film INS is patterned through a photolithography and etching process, so that the central via hole VHa and the outer via hole VHb penetrating the insulating film INS may be formed. At this time, the reflective electrode layer RL under the insulating film INS may be exposed through the central via hole VHa and the outer via hole VHb. Here, the width W1 of the central via hole VHa (for example, the size of the central via hole VHa in the first direction DR1) may be greater than the width W2 of the outer via hole VHb (for example, the size of the outer via hole VHb in the first direction DR1).

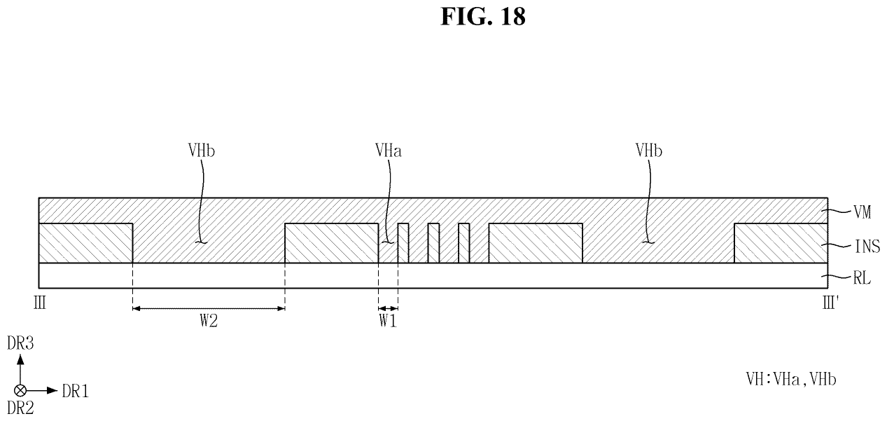

Subsequently, as shown in FIG. 18, a metal layer VM may be formed on the insulating film INS. The metal layer VM may be formed on top of the insulating film INS and in the central via hole VHa and the outer via hole VHb of the insulating film INS.

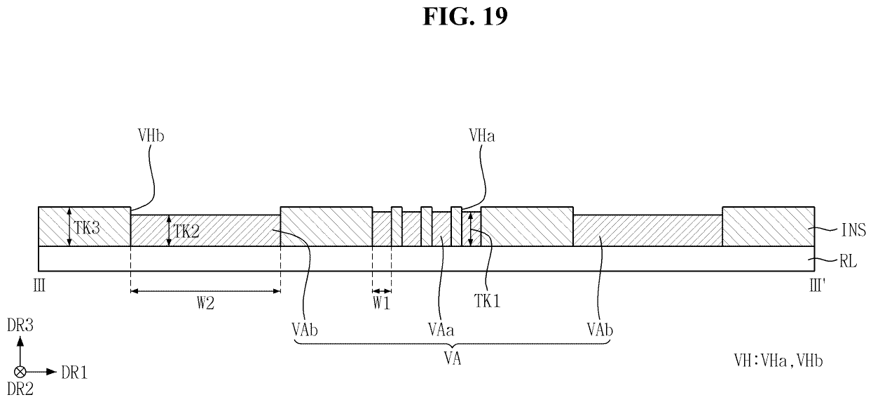

Next, a planarization process may be performed as shown in FIG. 19. For example, the metal layer VM on the insulating film INS may be removed through chemical mechanical polishing. Through this chemical mechanical polishing, the metal layer VM may remain in the central via hole VHa and the outer via hole VHb of the insulating film INS. In other words, the central metal portion VAa may be formed in the central via hole VHa, and the outer metal portion VAb may be formed in the outer via hole VHb. Here, due to a difference in etching rates of the metal layer VM and the insulating film INS, the metal layer VM may be removed more than the insulating film INS during the chemical mechanical polishing. Accordingly, as shown in FIG. 19, upon the completion of the chemical mechanical polishing process, the insulating film INS may have a greater thickness than the via VA (TK3>TK1, TK3>TK2). In addition, as the width of the central via hole VHa is smaller than the width of the outer via hole VHb, the central metal portion VAa in the central via hole VHa may have a greater thickness than the outer metal portion VAb in the outer via hole VHb (TK1>TK2). For example, the thickness TK1 of the central metal portion VAa may be greater than the thickness TK2 of the outer metal portion VAb and less than the thickness TK3 of the insulating film INS. Additionally, the width of the outer metal portion VAb may be greater than the width of the central metal portion VAa.

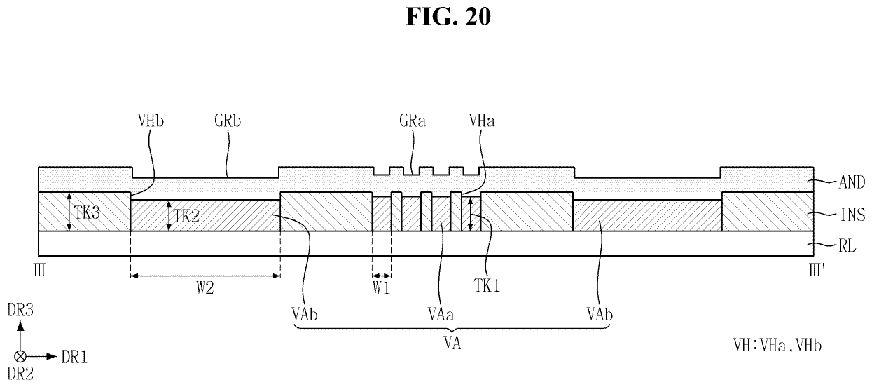

Subsequently, as shown in FIG. 20, the first electrode AND may be formed on the insulating film INS, the central metal portion VAa, and the outer metal portion VAb. The first electrode AND may have a stepped portion that follows the stepped portion (or thickness difference) of the structure underneath it (for example, the insulating film INS, the central metal portion VAa, and the outer metal portion VAb). For example, the first electrode AND may have the central groove GRa recessed in the third direction DR3 in the area overlapping the central metal portion VAa (for example, at the center of the emission area EA), and may have the outer groove GRb recessed in the third direction DR3 in the area overlapping the outer metal portion VAb (for example, at the edge of the emission area EA). The depth of the outer groove GRb may be greater than the depth of the central groove GRa. Here, the depth may be the size in the reverse third direction. Additionally, the width of the outer groove GRb may be greater than the width of the central groove GRa. The width of the outer groove GRb may be the same (or substantially the same) as the width of the outer via hole VHb, and the width of the central groove GRa may be the same (or substantially the same) as the width of the central via hole VHa.

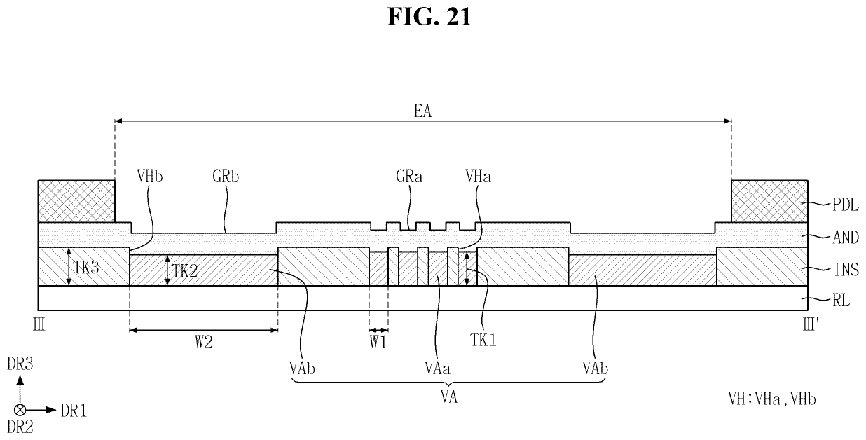

Next, as shown in FIG. 21, the pixel defining film PDL may be formed on the first electrode AND. For example, the pixel defining film PDL may be located on the edge of the first electrode AND. The emission area EA of the pixel may be defined by the pixel defining film PDL. The emission area EA may overlap the central groove GRa and the outer groove GRb of the first electrode AND. Additionally, the emission area EA may overlap the central metal portion VAa and the outer metal portion VAb.

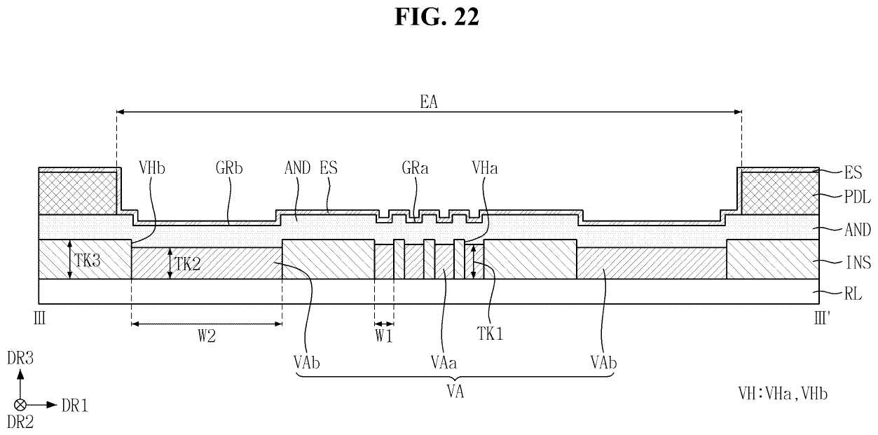

Subsequently, as shown in FIG. 22, the light-emitting stack ES may be formed on the pixel defining film PDL and the first electrode AND.

Next, as shown in FIG. 11, the second electrode CAT may be formed on the light-emitting stack ES.

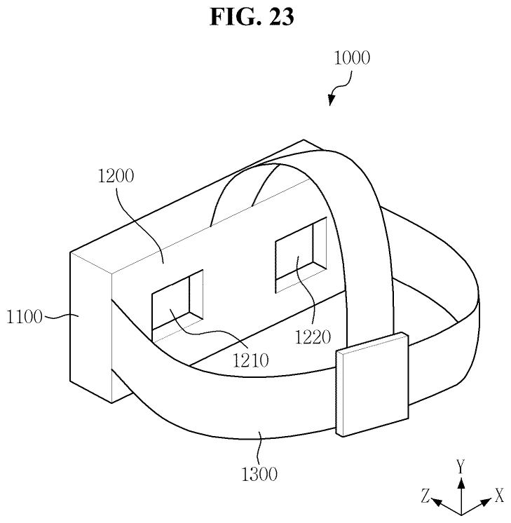

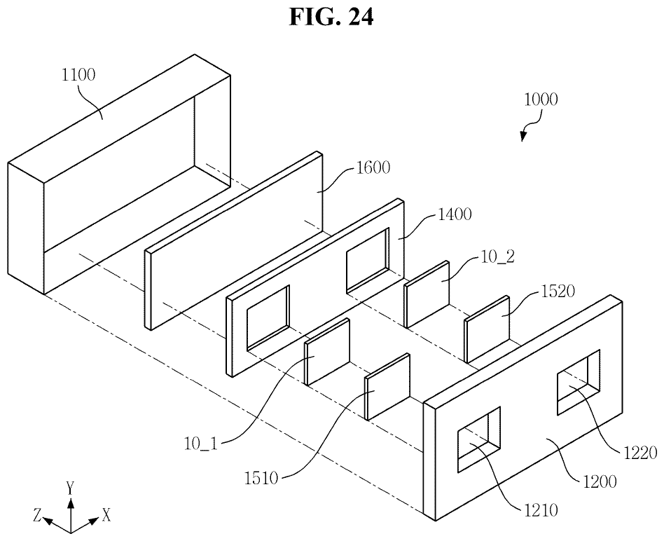

FIG. 23 is a perspective view illustrating a head mounted display according to some embodiments. FIG. 24 is an exploded perspective view illustrating an example of the head mounted display of FIG. 23.

Referring to FIGS. 23 and 24, a head mounted display 1000 according to some embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is the same (or substantially the same) as the display device 10 described in conjunction with FIGS. 1 to 22, description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is arranged to cover one open surface of the display device housing 1100. The housing cover 1200 may include the first eyepiece 1210 at which the user's left eye is located and the second eyepiece 1220 at which the user's right eye is located. FIGS. 23 and 24 illustrate that the first eyepiece 1210 and the second eyepiece 1220 are arranged separately, but the embodiments of the present disclosure are not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

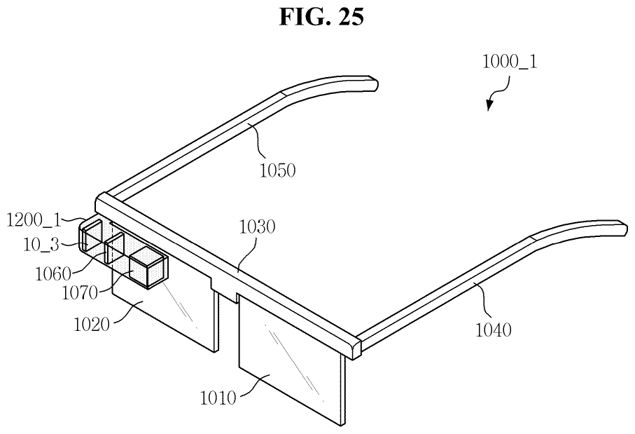

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with an eyeglass frame as shown in FIG. 25 instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 25 is a perspective view illustrating a head mounted display according to some embodiments.

Referring to FIG. 25, a head mounted display 1000_1 according to some embodiments may be an eyeglasses-type display device in which a display device housing 1200_1 is implemented in a lightweight and compact manner. The head mounted display 1000_1 according to some embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 25 illustrates that the display device housing 1200_1 is located at the right end of the support frame 1030, but the embodiments of the present disclosure are not limited thereto. For example, the display device housing 1200_1 may be located at the left end of the support frame 1030, and in this case, the image of the display device 10_3 may be provided to the user's left eye. Alternatively, the display device housing 1200_1 may be located at both the left and right ends of the support frame 1030, and in this case, the user may view the image displayed on the display device 10_3 through both the left and right eyes.

The display device according to the embodiment can be applied to various electronic devices. The electronic device according to one embodiment includes the display device described above and may further include modules or devices having additional functions in addition to the display device.

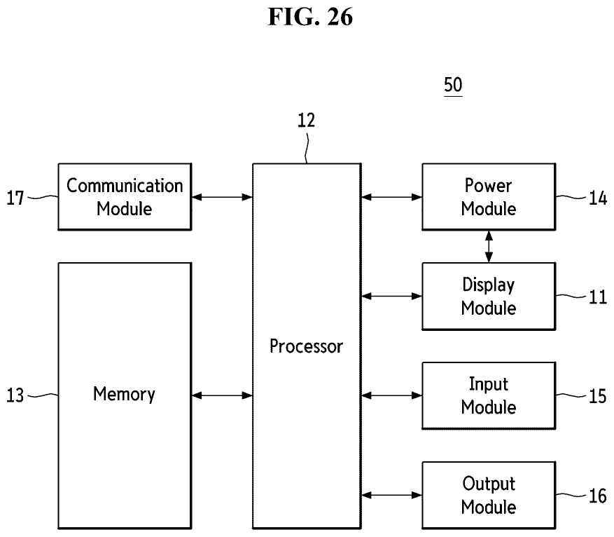

FIG. 26 is a block diagram of an electronic device according to one embodiment. Referring to FIG. 26, the electronic device 5000 according to one embodiment may include a display module 11, a processor 12, a memory 13, and a power module 14. The electronic device 50 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 50. The input module 15 may provide input information to the processor 12 and/or the display module 11. The output module 16 may receive information other than images transmitted from the processor 12, such as sound, haptics, and light, and provide the information to the user. The communication module 17 is a module that is responsible for transmitting and receiving information between the electronic device 50 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

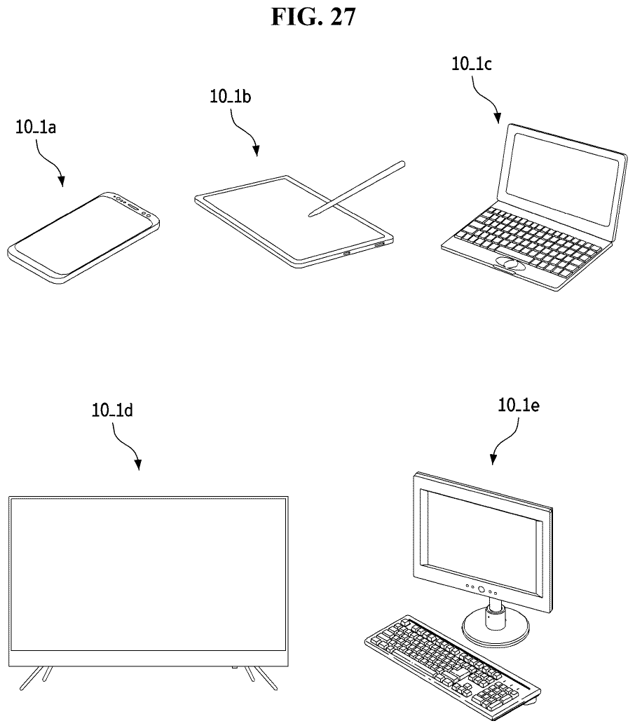

FIGS. 27, 28, and 29 are schematic diagrams of electronic devices according to various embodiments. FIGS. 27 to 29 illustrate examples of various electronic devices to which the display device according to the embodiments is applied.

FIG. 27 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

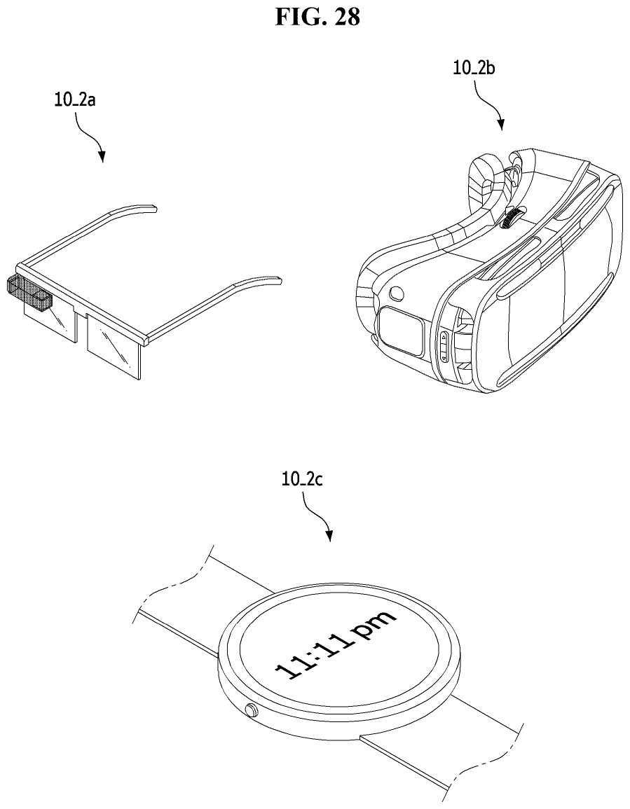

FIG. 28 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

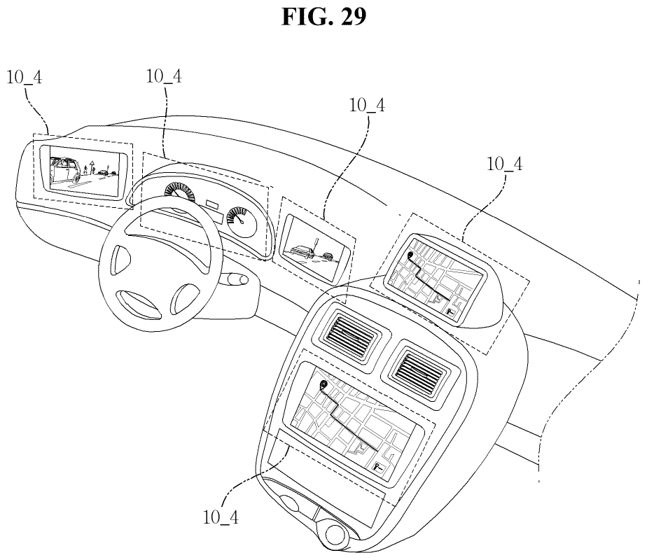

The smart watch 10_2c includes a biometric sensor as an input device, and may provide biometric information recognized by the biometric sensor to the user through the display module. FIG. 29 illustrates a case where an electronic device including a display module is applied to a vehicle. For example, the electronic device 10_4 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the technical spirit or essential features of the present disclosure. Therefore, it is to be understood that the disclosed embodiments described above are illustrative rather than being restrictive in all aspects. It is to be understood that the scope of the present disclosure are defined by the claims, and their equivalents, rather than the detailed description described above and all modifications and alterations derived from the claims and their equivalents fall within the scope of the present disclosure.

What is claimed is:

1. A display device comprising:
a substrate;
an insulating film on the substrate;
a central metal portion in a central via hole of the insulating film and an outer metal portion in an outer via hole of the insulating film;
a first electrode on the central metal portion and the outer metal portion;
a pixel defining film on the first electrode;
a light-emitting layer on the first electrode and the pixel defining film; and
a second electrode on the light-emitting layer,
wherein the central metal portion and the outer metal portion overlap an emission area defined by the pixel defining film.

2. The display device of claim 1, wherein in the emission area, a width of the outer metal portion is greater than a width of the central metal portion.

3. The display device of claim 1, wherein a thickness of the central metal portion is greater than a thickness of the outer metal portion.

4. The display device of claim 1, wherein a thickness of the insulating film is greater than a thickness of the central metal portion and a thickness of the outer metal portion.

5. The display device of claim 4, wherein the thickness of the central metal portion is greater than the thickness of the outer metal portion, and is less than the thickness of the insulating film.

6. The display device of claim 1, wherein the central metal portion overlaps a center of the emission area, and
the outer metal portion overlaps an edge of the emission area.

7. The display device of claim 1, wherein the first electrode has a central groove in an area overlapping the central metal portion, and has an outer groove in an area overlapping the outer metal portion.

8. The display device of claim 7, wherein a width of the outer groove is greater than a width of the central groove.

9. The display device of claim 7, wherein a depth of the outer groove is greater than a depth of the central groove.

10. The display device of claim 1, wherein in a plan view, an area of the outer metal portion is larger than an area of the central metal portion.

11. The display device of claim 1, wherein the central metal portion comprises a plurality of central metal portions spaced apart from each other.

12. The display device of claim 11, wherein in a plan view, an area of the outer metal portion is larger than a total area of the plurality of central metal portions.

13. The display device of claim 1, wherein in a plan view, the outer metal portion surrounds the central metal portion.

14. The display device of claim 1, wherein in a plan view, the emission area surrounds the central metal portion and the outer metal portion.

15. The display device of claim 1, wherein the central via hole and the outer via hole overlap the emission area.

16. The display device of claim 15, wherein in a plan view, the emission area surrounds the central via hole and the outer via hole.

17. The display device of claim 1, further comprising a reflective electrode layer under the insulating film.

18. The display device of claim 17, wherein the reflective electrode layer is connected to at least one of the central metal portion or the outer metal portion,
wherein the reflective electrode layer is connected to at least one of the central metal portion or the outer metal portion in the emission area.

19. The display device of claim 1, wherein the central metal portion and the outer metal portion do not overlap the pixel defining film.

20. An electronic device comprising:
a display device including a screen,
wherein the display device comprising:
a substrate;
an insulating film on the substrate;
a central metal portion in a central via hole of the insulating film and an outer metal portion in an outer via hole of the insulating film;
a first electrode on the central metal portion and the outer metal portion;
a pixel defining film on the first electrode;
a light-emitting layer on the first electrode and the pixel defining film; and
a second electrode on the light-emitting layer,
wherein the central metal portion and the outer metal portion overlap an emission area defined by the pixel defining film.
